(19) United States
(12) Patent Application Publication
(10) Pub. No.: US 2007/0161131 A1
(43) Pub. Date: Jul. 12, 2007

(54) Measurement method for low-k material

(75) Inventor: Cheon Man Shim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,094

(22) Filed: Dec. 26, 2006

(30) Foreign Application Priority Data
Dec. 28, 2005 (KR) 10-2005-0131485

(51) Int. Cl. H01L 21/66; H01L 21/31

(52) U.S. Cl. 438/14; 438/790; 257/E21.273; 257/E21.525

(57) ABSTRACT

Disclosed is a method for measuring a low-k material. A surface of the low-k material is changed into oxide by an oxygen plasma used in an ashing process (e.g., to remove a photoresist film after an etching process). A thickness of the low-k material is measured using an optical measurement system, and then the low-k material is treated with plasma in an ashing process to change the surface of the low-k material into oxide. The substrate is wet-cleaned with an inorganic or organic cleaning solution after the ashing process to remove the surface oxide. Then, a subsequent thickness of the low-k material is measured using the optical measurement system, and a thickness of the oxide is calculated by comparing the measured values. The thickness of a damaged low-k material is thereby measured in an easy and rapid manner since optical measurement system typically installed in the semiconductor fabrication facility (fab) is utilized.

### CROSS-REFERENCE TO RELATED APPLICATIONS

This application claims the benefit of Korean Patent Application No. 10-2005-0131485, filed on Dec. 28, 2005, in the Korean Intellectual Property Office, the disclosure of which is incorporated herein by reference.

### BACKGROUND OF THE INVENTION

1. Field of the Invention

The present invention relates to a semiconductor measurement technology, and more particularly to a method for measuring the thickness of a material that has a low dielectric constant, particularly of a damaged low-k material in an easy and rapid manner using an optical measurement system. The low-k material may be damaged, for example, after removing an oxide layer deformed through an ashing process by performing an inorganic cleaning (e.g., diluted HF) or an organic cleaning (e.g., NE14).

2. Description of the Related Art

Materials with a low dielectric constant k (e.g., materials in which k<3.0) have been used as intermetallic dielectric (IMD) materials for next-generation semiconductor metal interconnections, largely because low-k materials can reduce a resistance-capacitance (RC) delay effect. In particular, in order to implement highly integrated and high-speed semiconductor devices, both low-k dielectrics and high conductivity interconnection materials (e.g., copper wires) are used.

The combination of low-k dielectrics and high conductivity interconnection materials has several advantages. First, a decrease in RC signal delay is necessary for high-speed semiconductor device, in which the RC signal is represented as multiplication of the resistance of the interconnection material and the capacitance of the intermetallic dielectric (IMD) material. Second, the use of low-k dielectrics may prevent crosstalk so the circuits can be more densely packed, thus enabling high-integration and micro-sized semiconductor devices. Third, semiconductor technology has tended toward reduction of power consumption of semiconductor chips to support wireless and/or mobile applications (e.g., mobile telephones, wireless internet access, wireless headsets and other accessories, etc.). In this aspect, low-k materials can play an important role in reducing the power consumption of semiconductor chips.

However, low-k dielectrics may be vulnerable to oxidation. Oxygen (O₂) plasma is often used in an ashing process. The ashing process may be performed to remove a photoresist film after etching a metal layer to form metal interconnections. The ashing process may cause carbon in the low-k dielectric to be removed due a reaction between the dielectric and oxygen. As a result, the surface of the low-k dielectric is changed into an oxide (e.g., SiO₂, k=3.2˜4.2) causing an increase in the dielectric constant (k). Such an oxidized region of the low-k dielectric is referred to as a damaged region.

Therefore, it is desirable to reduce the damaged region in the low-k dielectric in order to prevent performance degradation of the semiconductor device. The amount of damage to the low-k dielectric can conventionally be measured by means of Fourier transform infrared spectroscopy (FTIR), secondary ion mass spectroscopy (SIMS) and/or Auger electron spectroscopy (AES).

However, since only a shallow thickness of the low-k dielectric surface is changed into oxide (relative to the total thickness of the low-k dielectric), Fourier transform infrared spectroscopy method, which uses infrared wavelengths, has insufficient resolution and/or insufficient precision to measure the damaged low-k dielectric. Furthermore, measurement of the thickness of the damaged low-k dielectric using secondary ion mass spectroscopy and Auger electron spectroscopy is problematic. With both methods, it is difficult to re-use a wafer because the wafer must be cut first. Furthermore, both methods require relatively long transportation and analysis times because analysis apparatuses are generally located outside of the semiconductor fabrication facility (fab).

### SUMMARY OF THE INVENTION

Accordingly, the present invention has been suggested to solve such drawbacks, and therefore, an object of the present invention is to provide a method for measuring a thickness of a low-k material that is capable of measuring a thickness of a damaged low-k material in an easy and rapid manner. The present invention uses an optical measurement system after removing an oxide layer deformed through an ashing process by performing an inorganic cleaning (e.g., diluted HF) or an organic cleaning (e.g., NE14).

To accomplish the above object, the present invention provides a method for measuring a low-k material (where k is the dielectric constant of the material). The method comprises the steps of forming a layer comprising the low-k material on a substrate, measuring a first thickness of the layer comprising the low-k material using an optical measurement system, changing a surface of the layer comprising the low-k material into oxide by treating the layer with an ashing process using plasma and forming an oxide layer thereby, removing the oxide layer by wet-cleaning, measuring a second thickness of the layer comprising the low-k material using the optical measurement system, and calculating a thickness of the oxide layer by comparing the first thickness with the second thickness.

The wet cleaning may include either inorganic or organic cleaning. Preferably, the inorganic cleaning employs fluoric acid diluted in a range of 10:1 to 1,000:1. In one exemplary embodiment, the optical measurement system includes thin film measurement equipment (such as a NanoSpec film analysis system produced by Nanometrics Inc.).

### BRIEF DESCRIPTION OF THE DRAWINGS

FIG. 1 is a sectional view showing a substrate formed with a layer comprising a low-k material;

FIG. 2 is a graph showing an analysis result for a low-k material after an ashing process, which is measured by means of secondary ion mass spectroscopy;

FIG. 3 is a graph showing an analysis result for a low-k material after an ashing process, which is measured by means of Auger electron spectroscopy;

FIG. 4 is a graph showing an amount of etched low-k materials when the low-k materials have been cleaned through inorganic and organic cleaning processes after an ashing process; and

FIG. 5 is a graph showing the thickness of the low-k material layer removed and the thickness of the low-k material layer remaining after cleaning using diluted fluoric acid after an ashing process.

### DETAILED DESCRIPTION OF PREFERRED EMBODIMENTS

Hereinafter, embodiments according to the present invention will be described with reference to the accompanying drawings.

In the following description of the present invention, technologies which are generally known in the art and do not directly relate to the present invention will be omitted in order to avoid redundancy and to clarify the subject matter of the present invention. In the same manner, some of elements are exaggerated, omitted, or simplified in the drawings and the elements may have sizes different from those shown in the drawings.

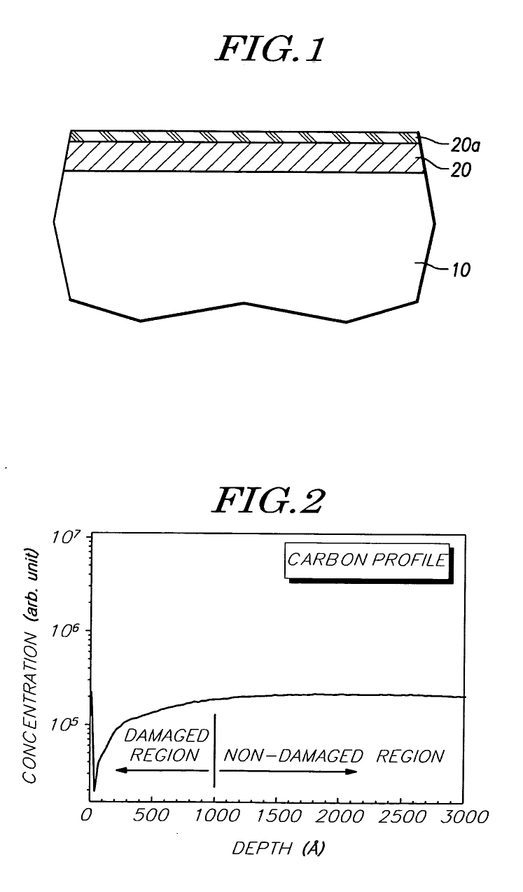

FIGS. 1 through 5 are cross-sectional views showing a method for measuring a low-k material according to preferred embodiments of the present invention.

Referring now to FIG. 1, a layer of low-k (e.g., wherein dielectric constant k<3.0) material 20 is formed on a substrate 10. The low-k material may comprise, for example, fluorosilicate glass (FSG), a silicon oxycarbide (SiOC), or a hydrogenated silicon oxycarbide (SiOCH). Then, the initial thickness of the layer of low-k material 20 is measured using an optical measurement system. For example, a thin film measurement apparatus, such as the NanoSpec film analysis system produced by Nanometrics Inc., can be used for measuring the thickness of the low-k material 20.

Next, the substrate 10 on which the layer of low-k material 20 is formed is treated with plasma through an ashing process. During the ashing process, oxygen (O₂) gas is fed to form plasma. At this time, a surface of the layer of low-k material 20 is changed into oxide (SiO₂) 20a having a dielectric constant of (k) of 3.2 to 4.2 because some carbon contained in the layer of low-k material 20 is combined with oxygen so that the carbon vanishes in the form of carbon dioxide due to oxygen plasma generated during the ashing process. Accordingly, the surface of the layer of low-k material 20 is deformed into an oxide layer 20a, which is considered a damaged region.

Subsequently, the substrate 10 is subject to wet cleaning using an inorganic solution such as diluted HF or organic solution such as NE14. At this time, the oxide layer 20a is etched from the surface of the layer of low-k material 20 formed on the substrate 10. During the inorganic cleaning process, the layer of low-k material 20 is etched for 12 seconds using fluoric acid (HF) diluted in a range of 10:1 to 1,000:1. Alternatively, during the organic cleaning process, the layer of low-k material 20 is etched using NE14 for one minute. Here, NE14 is an organic solvent which is used as cleaning solution and is commercially available from Airproduct Company.

Next, the thickness of the layer of low-k material 20 formed on the substrate 10 is secondarily measured using an optical measurement system. Here, a thickness of the oxide layer 20a (e.g., the damaged or deformed region) can be determined by comparing the initial thicknesses of the layer of low-k material 20 formed on the substrate 10 with the thickness of the layer of low-k material after the ashing process. Thus, it is possible to measure the thickness of the region in the layer low-k material 20 which is damaged (e.g., by oxidation of the surface of the layer of low-k material 20) through the ashing process.

When using the above method, the optical measurement system provided in the semiconductor fabrication facility (fab) can be utilized, so that the thickness of the damaged region in the layer of low-k material can be measured in an easy and rapid manner. Also, the semiconductor substrate is reusable because the substrate is not cut, so that the manufacturing cost can be reduced.

The thickness of the oxide layer 20a formed by the ashing process can be conventionally measured using secondary ion mass spectroscopy (SIMS) and/or Auger electron spectroscopy (AES).

Referring now to FIG. 2, a graph shows the amount of carbon contained in the layer low-k material, measured by using the secondary ion mass spectroscopy after a reactive ion etching (RIE) process and the ashing process. From the analysis of the carbon profile shown, it can be determined that a surface of the layer low-k material is damaged to a depth of about 1,000 Å through the ashing process (e.g., because the amount of the carbon is reduced through the ashing process).

FIG. 3 is a graph showing density of components obtained by analyzing a sample, which is identical to the sample used in FIG. 2, using Auger electron spectroscopy. A line 30 aligned in the vicinity of 230 Å from a surface of the sample represents an amount of oxide removed by the wet cleaning process. It can be seen from the graph that a relatively large amount of oxygen components exist on the surface (e.g., to a depth of approximately 350 Å˜400 Å) of the layer low-k material due to the ashing process.

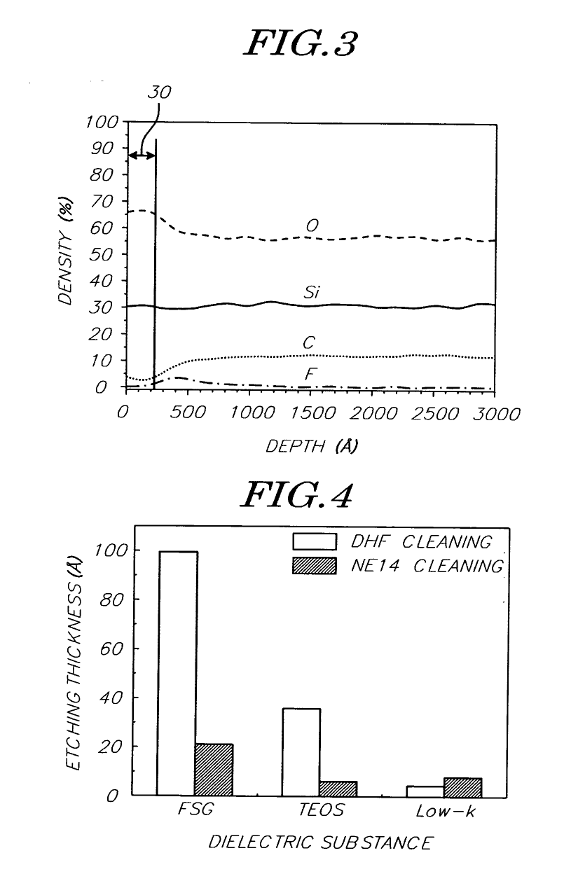

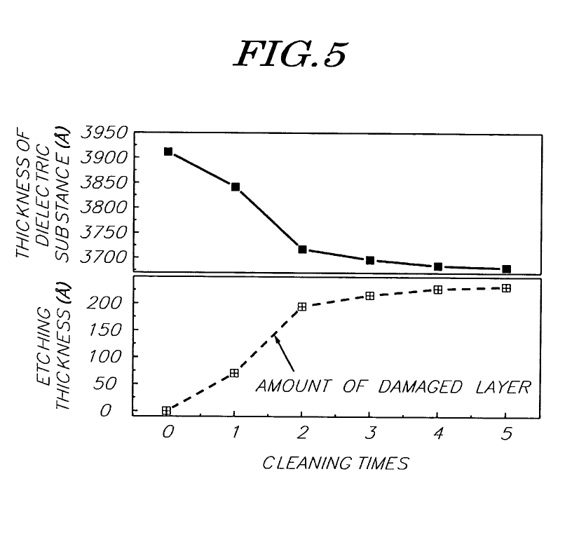

FIG. 4 is a graph showing the result of cleaning FSB (fluorine doped silicate glass), TEOS (tetraethyl ortho silicate) and the low-k material for 12 seconds using fluoric acid (inorganic cleaning) diluted at 100:1, and after cleaning FSB, TEOS and the low-k material using NE14 (organic solution) for one minute. As shown in FIG. 4, the FSB and TEOS are easily etched, but the low-k material is less readily etched (e.g., the low-k material has a high etch selectivity with respect to FSB and TEOS for both the inorganic and organic etch processes). From this result, it is recognized that the layer of low-k material is not substantially etched through inorganic or organic cleaning, if the layer of low-k material is not changed into oxide during the ashing process. That is, the thickness of the layer of low-k material removed by the cleaning process corresponds to the thickness of the oxide layer which is formed by the ashing process.

FIG. 5 is a graph showing the thickness of the remaining layer of low-k material and the thickness of the removed low-k material (e.g., the oxide layer) after the layer of low-k material has been cleaned for 12 seconds using fluoric acid diluted in a ratio of 100:1. As shown in the graph, the layer of low-k material is not etched any more after a sufficient time period has lapsed (e.g., after the oxide layer has been removed). At this time, the thickness of layer of low-k material has been reduced by about 230 Å. That is, the thickness of the etched region (e.g., the region of removed by the cleaning process is approximately 230 Å,

According to the method of the present invention, the thickness of the damaged (e.g., oxidized) layer of low-k material can be measured in an easy and rapid manner by using the optical measurement system installed in the semiconductor fabrication facility (fab).

In addition, according to the present invention, a wafer subjected to the present process is reusable since it is not necessary to cut the wafer during the measurement processes, resulting in reduced manufacturing costs.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for measuring a low-k material, the method comprising the steps of:
forming a low-k material on a substrate;
measuring a first thickness of the low-k material using an optical measurement system;
treating a surface of the low-k material with an ashing process using plasma and forming an oxide layer thereby;
removing the oxide layer by wet-cleaning;
measuring a second thickness of the low-k material using the optical measurement system; and
calculating a thickness of the oxide layer by comparing the first thickness with the second thickness.

2. The method of claim 1, wherein the wet cleaning includes inorganic cleaning.

3. The method of claim 2, wherein the inorganic cleaning employs diluted HF.

4. The method of claim 3, wherein the inorganic cleaning employs hydrofluoric acid diluted in a range of 10:1 to 1,000:1.

5. The method of claim 1, wherein the wet cleaning includes organic cleaning.

6. The method of claim 1, wherein the organic cleaning employs NE14.

7. The method of claim 1, wherein the optical measurement system includes a thin film measurement apparatus.

8. The method of claim 1, wherein the plasma comprises oxygen gas.

9. The method of claim 1, wherein the oxide layer comprises SiO₂.

10. The method of claim 1, wherein the low-k material is a fluorosilicate glass (FSG), a silicon oxycarbide (SiOC), or a hydrogenated silicon oxycarbide (SiOCH).

11. The method of claim 1, wherein the forming the low-k material on the substrate comprises forming a layer of the low-k material on the substrate.
